(19) United States
(12) Patent Application Publication
(10) Pub. No.: US 2013/0057812 A1
(43) Pub. Date: Mar. 7, 2013

(54) LIQUID CRYSTAL DISPLAY AND METHOD FOR MANUFACTURING THE SAME

(71) Applicants: Chang Hun KWAK, Suwon-si (KR); Chul HUH, Yongin-si (KR); Myung Jin LEE, Hwaseong-si (KR); Min Jung KANG, Incheon (KR)

(72) Inventors: Chang Hun KWAK, Suwon-si (KR); Chul HUH, Yongin-si (KR); Myung Jin LEE, Hwaseong-si (KR); Min Jung KANG, Incheon (KR)

(73) Assignee: SAMSUNG DISPLAY CO., LTD., Yongin-City (KR)

(21) Appl. No.: 13/461,559

(22) Filed: May 1, 2012

(30) Foreign Application Priority Data
Sep. 7, 2011 (KR) 10-2011-0090617

(51) Int. Cl. G02F 1/1335; H01L 33/08

(52) U.S. Cl. 349/106; 438/30; 257/E33.012

(57) ABSTRACT

A liquid crystal display according to an exemplary embodiment of the invention includes: a first substrate, a second substrate which faces the first substrate, a sealant which adheres the first substrate and the second substrate together, light blocking members disposed on at least one of the first substrate and the second substrate, a color filter between light blocking members, a dummy color filter on a light blocking member in the peripheral area, and an overcoat on at least one of the color filter and the dummy color filter. An upper surface of the overcoat in the peripheral area comprises protrusions.

This application claims priority to Korean Patent Application No. 10-2011-0090617 filed on Sep. 7, 2011, and all the benefits accruing therefrom under 35 U.S.C. §119, the entire contents of which are incorporated herein by reference.

### BACKGROUND OF THE INVENTION

(a) Field of the Invention

The invention relates to a liquid crystal display and a manufacturing method. (b) Description of the Related Art

A liquid crystal display (“LCD”), which is one of the most common types of flat panel displays in use, includes two sheets of display panels on which electrodes are formed and a liquid crystal layer interposed therebetween, and controls the amount of light transmitted by applying voltages to the electrodes.

Among the LCDs, an LCD having a structure in which field generating electrodes are respectively formed on two display panels is widely used. Among the two display panels, a plurality of pixel electrodes and thin film transistors are arranged in a matrix format on one display panel (hereinafter referred to as “a thin film transistor array panel”), and a common electrode covers the entire surface of the other display panel (hereinafter referred to as “a common electrode panel”).

The common electrode panel includes a color filter displaying a color and an overcoat preventing a step due to the color filter.

Moisture is penetrated into the overcoat of the edge of the liquid crystal display and the interface of the common electrode such that a stain may be generated.

### BRIEF SUMMARY OF THE INVENTION

The invention prevents penetration of moisture into the edge of a liquid crystal display.

A liquid crystal display according to an exemplary embodiment of the invention includes: a first substrate, a second substrate which faces the first substrate, a sealant which adheres the first substrate and the second substrate together, light blocking members disposed on at least one of the first substrate and the second substrate, a color filter between light blocking members, a dummy color filter on a light blocking member in the peripheral area, and an overcoat on at least one of the color filter and the dummy color filter. A lower surface of the overcoat in the peripheral area comprises protrusions and depressions.

A surface roughness (Ra) of the overcoat in the peripheral area may be about 30 nanometers to about 100 nanometers.

The lower surface of overcoat in the display area may be flat.

The liquid crystal display may comprise a common electrode on the overcoat, a lower surface of the common electrode in the peripheral area may comprise protrusions and depressions and a surface roughness (Ra) of the common electrode in the peripheral area may be about 10 nanometers to about 30 nanometers.

The dummy color filter may comprise a plurality of discrete patterns of a quadrangle shape.

The color filter may include red, green, and blue colors, and the dummy color filter may include at least one of red, green, and blue colors.

A manufacturing of method of a liquid crystal display according to an exemplary embodiment of the invention includes: forming a thin film transistor array panel including a first substrate including a display area and a peripheral area, a thin film transistor on the first substrate, and a pixel electrode which is connected to the thin film transistor; forming a common electrode panel, and combining the thin film transistor array panel and the common electrode panel by using a sealant. The forming the common electrode panel includes forming light blocking members in the display area and the peripheral area, on a second substrate; forming a color filter between light blocking members in the display area on the second substrate, and a dummy color filter on a light blocking member in the peripheral area; forming an overcoat on the color filter in the display area and the dummy color filter in the peripheral area; forming a common electrode on the overcoat. The forming the overcoat in the peripheral area includes forming protrusions and depressions in a lower surface of the overcoat adjacent to the common electrode.

The forming the common electrode in the peripheral area may include forming protrusions and depressions in a lower surface of the common electrode, and a surface roughness (Ra) of the common electrode in the peripheral area may be about 10 nanometers to about 30 nanometers.

The forming the overcoat further may include forming the lower surface of the overcoat in the display area to flat.

The forming the color filter and the dummy color filter may include coating a pigment layer on the second substrate and the light blocking members, exposing the pigment layer by using a mask, and developing the exposed pigment layer.

The mask may include a light blocking part, a transmitting part, and a slit part.

The pigment layer may have one of red, green, and blue colors.

A liquid crystal display according to another exemplary embodiment of the invention includes: a first substrate including a display area and a peripheral area; a thin film transistor on the first substrate; light blocking members in the display area on the first substrate and the thin film transistor, and the peripheral area; a color filter between light blocking members in the display area, on the first substrate; a dummy color filter on a light blocking member in the peripheral area; a passivation layer on the color filter in the display area and the dummy color filter in the peripheral area; and a pixel electrode on the passivation layer and connected to the thin film transistor. An upper surface of the passivation layer in the peripheral area includes protrusions and depressions.

A surface roughness (Ra) of the passivation layer in the peripheral area may be about 30 nanometers to about 100 nanometers.

The upper surface of passivation layer in the display area may be flat.

According to exemplary embodiments of the invention, moisture penetration through the interface of the overcoat and the common electrode and the interface of the common electrode and the sealant may be reduced or effectively prevented by the protrusions and depressions at the surface of the overcoat and the protrusions and depressions at the surface of the common electrode.

Also, the moisture penetration through the interface of the passivation layer and the sealant may be reduced or effectively prevented by the protrusions and depressions at the surface of the passivation layer.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is a top plan view of an exemplary embodiment of a liquid crystal display according to an exemplary embodiment according to an exemplary embodiment of the present invention.

FIG. 2 is a cross-sectional view taken along line II-II of FIG. 1.

FIG. 3 to FIG. 8 are views sequentially showing an exemplary embodiment of a manufacturing method of a common electrode panel according to the invention.

FIG. 9 is a cross-sectional view of another exemplary embodiment a liquid crystal display according to the invention.

FIG. 10 to FIG. 15 are views sequentially showing an exemplary embodiment of a manufacturing method of a thin film transistor array panel according to the invention.

### DETAILED DESCRIPTION OF THE INVENTION

The invention will be described more fully hereinafter with reference to the accompanying drawings, in which exemplary embodiments of the invention are shown. As those skilled in the art would realize, the described embodiments may be modified in various different ways, all without departing from the spirit or scope of the invention.

In the drawings, the thickness of layers, films, panels, regions, etc., are exaggerated for clarity. Like reference numerals designate like elements throughout the specification. As used herein, the term “and/or” includes any and all combinations of one or more of the associated listed items. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

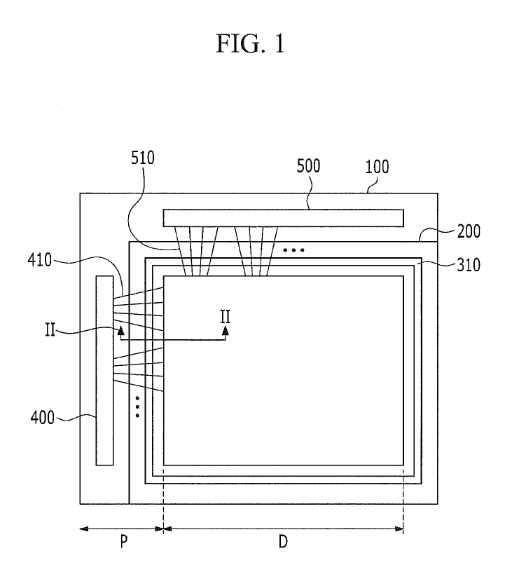

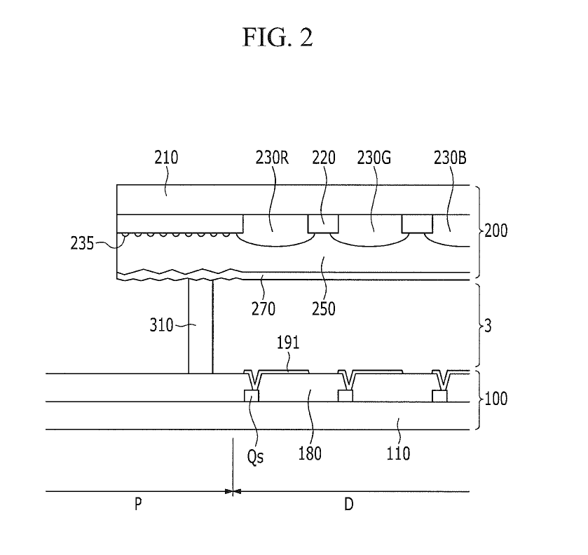

Now, an exemplary embodiment of a liquid crystal display according to the invention will be described with reference to FIG. 1 and FIG. 2.

FIG. 1 is a top plan view of an exemplary embodiment of a liquid crystal display according to the invention, and FIG. 2 is a cross-sectional view taken along line II-II of FIG. 1.

As shown in FIG. 1 and FIG. 2, a liquid crystal display according to the invention includes a thin film transistor array panel 100 and a common electrode panel 200 facing each other, and a liquid crystal layer 3 disposed between the two display panels 100 and 200. The thin film transistor array panel 100 and the common electrode panel 200 are attached to each other by a sealant 310, and the liquid crystal layer 3 is blocked from the outside by the sealant 310, thereby filling a space between the two display panels 100 and 200.

The thin film transistor array panel 100 is divided into a display area D displaying an image, and a peripheral area P including a gate driving circuit 400 and a data driving circuit 500 supplying electrical signals applied to the display area D, and a plurality of wires 410 and 510 to connect the gate driving circuit 400 and the data driving circuit 500, respectively, with the display area D.

The display area D includes a thin film transistor Qs on a first substrate 110 including an insulating material such as glass or plastic, and a passivation layer 180 on the thin film transistor Qs. The passivation layer 180 is extended to the peripheral area P. A pixel electrode 191 connected to the thin film transistor Qs is on the passivation layer 180.

The common electrode panel 200 facing the thin film transistor array panel 100 includes light blocking members 220 on a second substrate 210 including an insulating material such as glass or plastic, and red, green and blue color filters 230R, 230G, and 230B between the light blocking members 220 in a plan view and on the second substrate 210. The light blocking members 220 are extended to and disposed in the peripheral area P.

A dummy color filter 235 is on the light blocking member 220 positioned in the peripheral area P. The dummy color filter 235 may have a quadrangle pattern in the plan view of a minute size or a pattern of different shapes. Also, the dummy color filter 235 may be one of a red, green, and blue filter.

An overcoat 250 is on the red, green, and blue color filters 230R, 230G, and 230B and the dummy color filter 235. The overcoat 250 prevents a step due to the red, green, and blue color filters 230R, 230G, and 230B, and the lower surface of the portion of the overcoat 250 corresponding to the display area D is flat (e.g., planar). The lower surface of the portion of the overcoat 250 corresponding to the peripheral area P is non-planar and includes protrusions and depressions. A surface roughness (Ra) of the overcoat 250 in the peripheral area P is about 30 nanometers to about 100 nanometers.

A common electrode 270 is on the overcoat 250. The lower surface of the portion of the common electrode 270 corresponding to the display area D is flat (e.g., planar), and the lower surface of the common electrode 270 corresponding to the peripheral area P is non-planar and includes protrusions and depressions. A surface roughness (Ra) of the common electrode 270 in the peripheral area P is about 10 nanometers to about 30 nanometers.

The sealant 310 is positioned in the peripheral area P and adheres the thin film transistor array panel 100 and the common electrode panel 200 together.

In a conventional liquid crystal display, moisture penetrates into the interface of the overcoat 250 of the peripheral area P and the common electrode 270 and the interface of the common electrode 270 and the sealant 310, but in the exemplary embodiment, the interface of the overcoat 250 and the common electrode 270 in the peripheral area P is modified by the protrusions and depressions at the lower surface of the overcoat 250, and the interface of the common electrode 270 and the sealant 310 is modified by the protrusions and depressions at the lower surface of the common electrode 270.

Accordingly, moisture penetration through the interface of the overcoat 250 and the common electrode 270 and moisture penetration through the interface of the common electrode 270 and the sealant 310 may be reduced or effectively prevented by the protrusions and depressions at the lower surface of the overcoat 250 and the protrusions and depressions at the lower surface of the common electrode 270, respectively.

Also, the adherence of the overcoat 250 and the common electrode 270 to each other is improved by the protrusions and depressions at the lower surface of the overcoat 250, and the adherence of the common electrode 270 and the sealant 310 is improved by the protrusions and depressions at the lower surface of the common electrode 270.

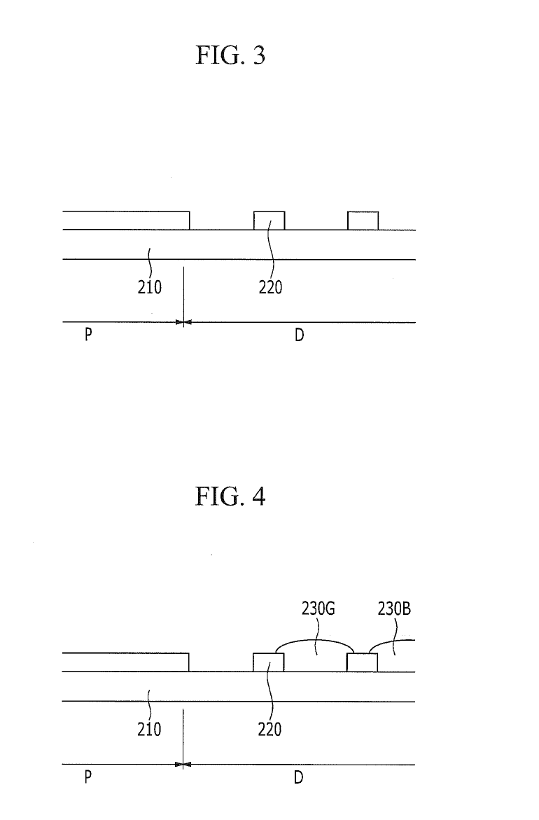

An exemplary embodiment of a manufacturing method of a common electrode panel according to the invention will now be described with reference to FIG. 3 to FIG. 8.

FIG. 3 to FIG. 8 are views sequentially showing an exemplary embodiment of a manufacturing method of a common electrode panel according to the invention.

As shown in FIG. 3, the light blocking member 220 is formed directly on the second substrate 210. The light blocking member 220 is extended to the peripheral area P.

As shown in FIG. 4, a green color filter 230G and a blue color filter 230B are formed between adjacent light blocking members 220 and directly on the second substrate 210.

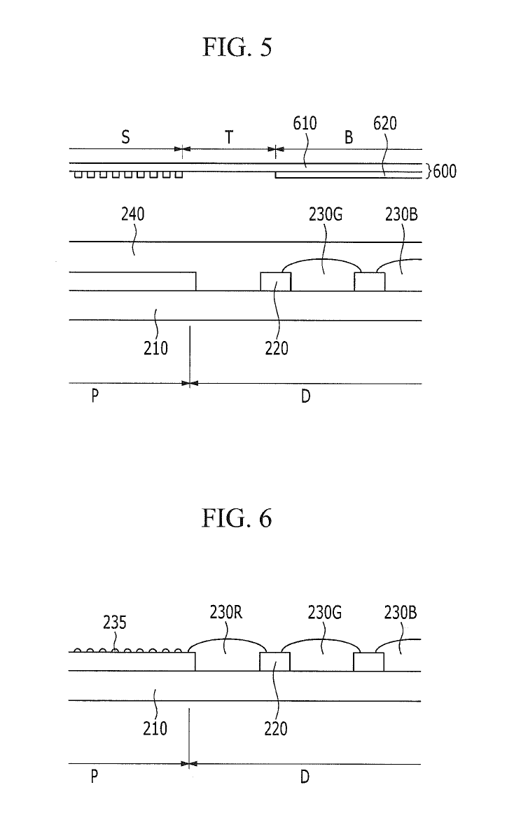

As shown in FIG. 5, a red pigment layer 240 is coated directly on the second substrate 210 and the light blocking member 220, and the red pigment layer 240 is exposed by using a mask 600. The mask 600 includes a transparent substrate 610 and a light blocking layer 620, and includes a light blocking part B, a transmitting part T, and a slit part S. The light blocking layer 620 is formed to completely block the light in the light blocking part B, is formed of a slit or a semi-transparent layer in the slit part S to partially transmit the light, and is removed in the transmission part T.

In the exemplary embodiment, the red pigment layer 240 is formed with a material having negative photosensitivity, and when the red pigment layer 240 is formed with a material having positive photosensitivity, the light blocking layer 620 is removed to transmit the light in the light blocking part B, is formed with the slit or the semi-transmitting layer to partially transmit the light in the slit part S, and is continuously formed with the light blocking layer 620 in the transmitting part T to completely block the light.

As shown in FIG. 6, the exposed red pigment layer 240 is developed to form the red color filter 230R and the dummy color filter 235. The dummy color filter 235 is positioned on the light blocking member 220 positioned in the peripheral area P. The dummy color filter 235 has a quadrangle pattern or variously shaped discrete patterns of a minute size.

In the exemplary embodiment, the dummy color filter 235 and the red color filter 230R are formed with the same material, however the dummy color filter 235 may be formed with the same material as the green color filter 230G or the blue color filter 230B.

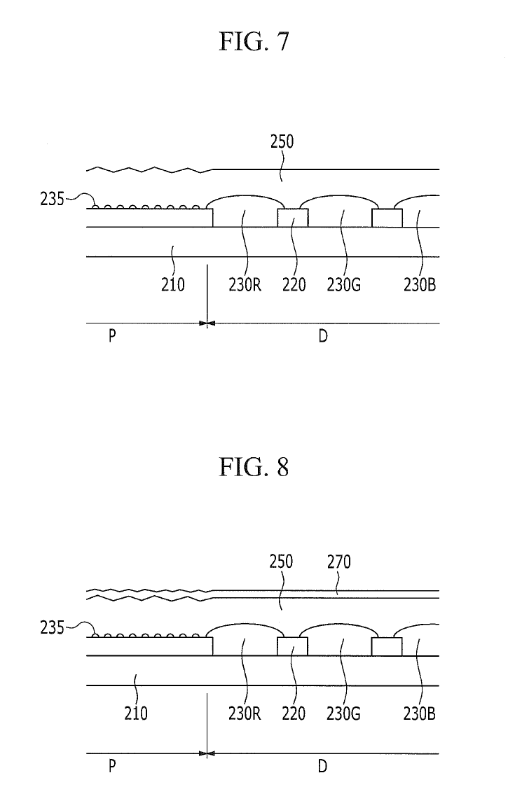

As shown in FIG. 7, the overcoat 250 is formed directly on the red, green, and blue color filters 230R, 230G, and 230B and the dummy color filter 235. The lower surface of the portion of the overcoat 250 corresponding to the display area D is flat. Protrusions and depressions are formed by the dummy color filter 235 in the lower surface of the portion of the overcoat 250 corresponding to the peripheral area P. These protrusions and depressions are formed by the dummy color filter 235, and a surface roughness (Ra) of the overcoat 250 in the peripheral area P is about 30 nanometers to about 100 nanometers.

As described above, the non-planar lower surface of the overcoat 250 in the peripheral area P is formed by disposing overcoat material directly on and overlapping the non-planar lower surface of the dummy color filter 235 in the peripheral area P. The non-planar lower surface of the overcoat 250 in a final common electrode panel 200 is considered a structural characteristic the final common electrode panel 200 and of a final liquid crystal display. Since the non-planar structure of the overcoat 250 is imparted by disposing the overcoat material directly on and overlapping the non-planar lower surface of the dummy color filter 235, such process is considered to impart the distinct structural characteristic of the non-planar lower surface of the overcoat 250.

As shown in FIG. 8, the common electrode 270 is formed directly on the overcoat 250. The lower surface of the portion of the common electrode 270 corresponding to the display area D is flat, however the protrusions and depressions are formed in the lower surface of the portion of the common electrode 270 corresponding to the peripheral area P. These protrusions and depressions are formed by the protrusions and depressions of the overcoat 250, and a surface roughness (Ra) of the common electrode 270 in the peripheral area P is about 10 nanometers to about 30 nanometers.

As described above, the non-planar lower surface of the common electrode 270 in the peripheral area P is formed by disposing common electrode material directly on and overlapping the non-planar lower surface of the overcoat 250 in the peripheral area P. The non-planar lower surface of the common electrode 270 in a final common electrode panel 200 is considered a structural characteristic the final common electrode panel 200 and of a final liquid crystal display. Since the non-planar structure of the common electrode 270 is imparted by disposing the common electrode material directly on and overlapping the non-planar lower surface of the overcoat 250, such process is considered to impart the distinct structural characteristic of the non-planar lower surface of the common electrode 270.

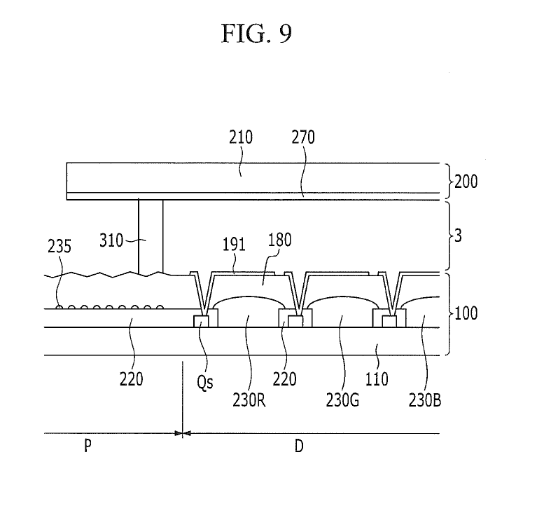

Next, another exemplary embodiment of a liquid crystal display according to the invention will be described with reference to FIG. 9 to FIG. 15.

FIG. 9 is a cross-sectional view of another exemplary embodiment of a liquid crystal display according to the invention.

As shown in FIG. 9, unlike the liquid crystal display according to FIG. 2, in the liquid crystal display according to the exemplary embodiment, red, green, and blue color filters 230R, 230G, and 230B and a light blocking member 220 are in a thin film transistor array panel 100.

The liquid crystal display according to the exemplary embodiment includes a thin film transistor array panel 100, a common electrode panel 200 facing the thin film transistor array panel 100, and a liquid crystal layer 3 interposed between the two display panels 100 and 200. The thin film transistor array panel 100 and the common electrode panel 200 are adhered to each other by a sealant 310, and the liquid crystal layer 3 is blocked by the sealant 310 from the outside thereby filling the space between the two display panels 100 and 200.

The display area D of the thin film transistor array panel 100 includes a thin film transistor Qs on the first substrate 110 which includes the insulating material such as glass or plastic, and a light blocking member 220 on the thin film transistor Qs. Red, green, and blue color filters 230R, 230G, and 230B are between the light blocking members 220 on the first substrate 110. The light blocking member 220 is extended to the peripheral area P.

A dummy color filter 235 is on the light blocking member 220 positioned in the peripheral area P. The dummy color filter 235 may have the quadrangle pattern in the plan view or the pattern of various shapes of a minute size. Also, the dummy color filter 235 may be one of a red, green, and blue filter.

A passivation layer 180 is on the red, green, and blue color filters 230R, 230G, and 230B and the dummy color filter 235. The passivation layer 180 is extended to the peripheral area P. The upper surface of the portion of the passivation layer 180 corresponding to the display area D is flat and the upper surface of the portion of the passivation layer 180 corresponding to the peripheral area P is non-planar and includes the protrusions and depressions. A surface roughness (Ra) of the passivation layer 180 in the peripheral area P is about 30 nanometers to about 100 nanometers

A pixel electrode 191 connected to the thin film transistor Qs is in the display area D and on the passivation layer 180.

A common electrode panel 200 facing the thin film transistor array panel 100 includes a common electrode 270 on the second substrate 210 including the insulating material such as glass or plastic.

The sealant 310 is positioned in the peripheral area P, and adheres the thin film transistor array panel 100 and the common electrode panel 200 together.

In a conventional liquid crystal display, the moisture penetrates into the interface of the passivation layer 180 and the sealant 310 in the peripheral area P, but in the exemplary embodiment, the interface of the passivation layer 180 and the sealant 310 in the peripheral area P is modified by the protrusions and depressions at the upper surface of the passivation layer 180.

Accordingly, the moisture penetration through the interface of the passivation layer 180 and the sealant 310 may be reduced or effectively prevented by the protrusions and depressions at the upper surface of the passivation layer 180.

Also, the adherence of the passivation layer 180 and the sealant 310 to each other is improved by the protrusions and depressions at the upper surface of the passivation layer 180.

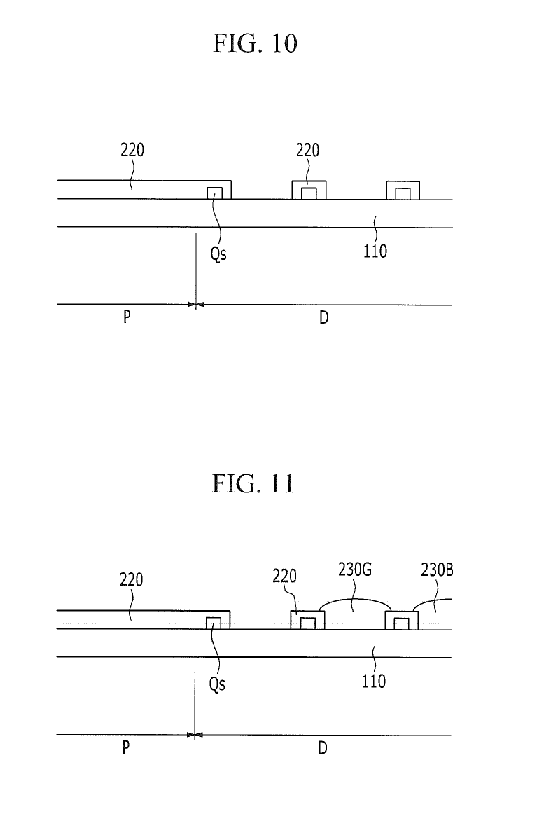

Next, an exemplary embodiment of a manufacturing method of a thin film transistor array panel according to the invention will be described with reference to FIG. 10 to FIG. 15.

FIG. 10 to FIG. 15 are views sequentially showing an exemplary embodiment of a manufacturing method of a thin film transistor array panel according to the invention.

As shown in FIG. 10, the thin film transistor Qs is formed directly on the first substrate 110, and a light blocking member 220 is formed directly on the thin film transistor Qs. The light blocking member 220 is extended to the peripheral area P.

As shown in FIG. 11, a green color filter 230G and a blue color filter 230B are formed between adjacent light blocking members 220 and directly on the first substrate 110.

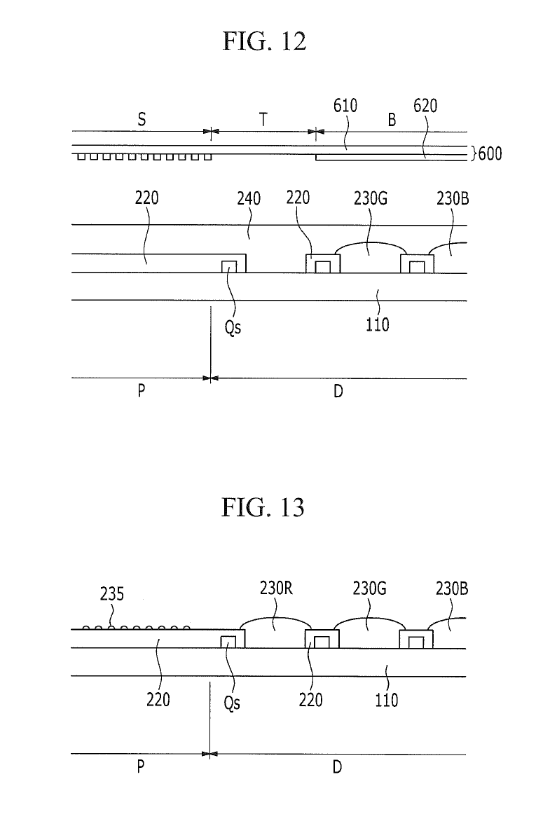

As shown in FIG. 12, a red pigment layer 240 is coated directly on the first substrate 110 and the light blocking member 220, and the red pigment layer 240 is exposed by using the mask 600. The mask 600 includes a transparent substrate 610 and a light blocking layer 620, and includes a light blocking part B, a transmitting part T, and a slit part S. The light blocking layer 620 is formed to completely block the light in the light blocking part B, is formed of a slit or a semi-transparent layer in the slit part S to partially transmit the light, and is removed in the transmission part T.

In the exemplary embodiment, the red pigment layer 240 is formed with a material having negative photosensitivity, and when the red pigment layer 240 is formed with a material having positive photosensitivity, the light blocking layer 620 is removed to transmit the light in the light blocking part B, is formed with the slit or the semi-transmitting layer to partially transmit the light in the slit part S, and is continuously formed with the light blocking layer 620 in the transmitting part T to completely block the light.

As shown in FIG. 13, the exposed red pigment layer 240 is developed to form a red color filter 230R and a dummy color filter 235. The dummy color filter 235 is positioned on the light blocking member 220 positioned in the peripheral area P. The dummy color filter 235 has a quadrangle pattern or variously shaped discrete patterns of a minute size.

In the exemplary embodiment, the dummy color filter 235 and the red color filter 230R are formed with the same material, however the dummy color filter 235 may be formed with the same material as the green color filter 230G or the blue color filter 230B.

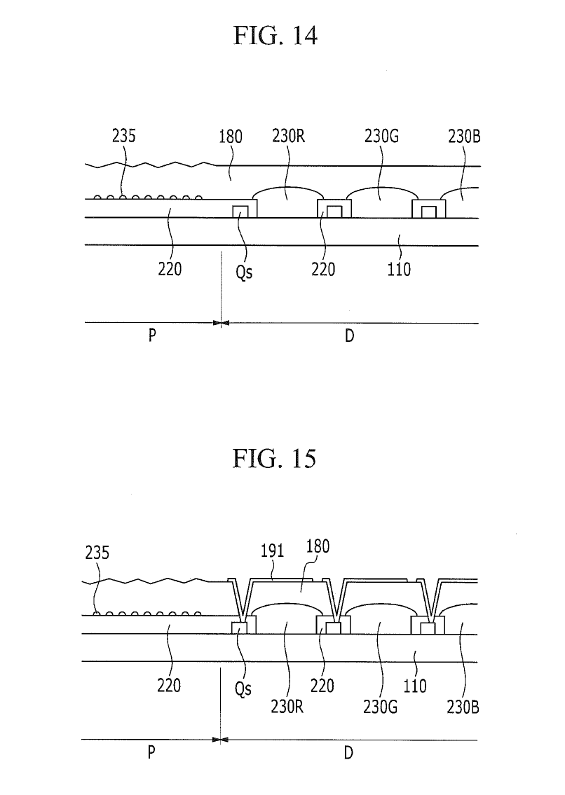

As shown in FIG. 14, the passivation layer 180 is formed directly on the red, green, and blue color filters 230R, 230G, and 230B and the dummy color filter 235. The upper surface of the portion of the passivation layer 180 corresponding to the display area D is flat. Protrusions and depressions are formed by the dummy color filter 235 in the upper surface of the portion of the passivation layer 180 corresponding to the peripheral area P. These protrusions and depressions are formed by the dummy color filter 235, and a surface roughness (Ra) of the passivation layer 180 in the peripheral area P is about 30 nanometers to about 100 nanometers.

As described above, the non-planar upper surface of the passivation layer 180 in the peripheral area P is formed by disposing passivation layer material directly on and overlapping the non-planar upper surface of the dummy color filter 235 in the peripheral area P. The non-planar upper surface of the passivation layer 180 in a final thin film transistor array panel 100 is considered a structural characteristic the final thin film transistor panel 100 and of a final liquid crystal display. Since the non-planar structure of the passivation layer 180 is imparted by disposing the passivation layer material directly on and overlapping the non-planar upper surface of the dummy color filter 235, such process is considered to impart the distinct structural characteristic of the non-planar upper surface of the passivation layer 180.

As shown in FIG. 15, a pixel electrode 191 is formed in the display area D on the passivation layer 180. The pixel electrode 191 is connected to the thin film transistor Qs through a contact hole which extends completely through a thickness of the passivation layer 180.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A liquid crystal display comprising:
a first substrate;
a second substrate which faces the first substrate;
a sealant which adheres the first substrate and the second substrate together;
light blocking members disposed on at least one of the first substrate and the second substrate;
a color filter between light blocking members;
a dummy color filter on a light blocking member in a peripheral area; and
an overcoat on at least one of the color filter and the dummy color filter,
wherein an lower surface of the overcoat in the peripheral area comprises protrusions and depressions.

2. The liquid crystal display of claim 1, wherein a surface roughness (Ra) of the overcoat in the peripheral area is about 30 nanometers to about 100 nanometers.

3. The liquid crystal display of claim 2, wherein the lower surface of the overcoat in the display area is flat.

4. The liquid crystal display of claim 3, further comprising a common electrode on the overcoat, wherein an lower surface of the common electrode in the peripheral area comprises protrusions and depressions and a surface roughness (Ra) of the common electrode in the peripheral area is about 10 nanometers to about 30 nanometers.

5. The liquid crystal display of claim 1, wherein the dummy color filter comprises a plurality of discrete patterns of a quadrangle shape.

6. The liquid crystal display of claim 5, wherein the color filter includes red, green, and blue colors, and the dummy color filter includes at least one of red, green, and blue colors.

7. A method of manufacturing a liquid crystal display, the method comprising:
forming a thin film transistor array panel including a first substrate including a display area and a peripheral area, a thin film transistor on the first substrate, and a pixel electrode which is connected to the thin film transistor;
forming a common electrode panel, and
combining the thin film transistor array panel and the common electrode panel by using a sealant,
wherein the forming a common electrode panel includes:
forming light blocking members in the display area and the peripheral area, on a second substrate;
forming a color filter between light blocking members in the display area on the second substrate, and a dummy color filter on a light blocking member in the peripheral area;
forming an overcoat on the color filter in the display area and the dummy color filter in the peripheral area;
forming a common electrode on the overcoat,
wherein the forming the overcoat in the peripheral area includes forming protrusions and depressions in a lower surface of the overcoat adjacent to the common electrode.

8. The method of claim 7, wherein a surface roughness (Ra) of the overcoat in the peripheral area is about 30 nanometers to about 100 nanometers.

9. The method of claim 8, wherein the forming the common electrode in the peripheral area includes forming protrusions and depressions in a lower surface of the common electrode, and a surface roughness (Ra) of the common electrode in the peripheral area is about 10 nanometers to about 30 nanometers.

10. The method of claim 9, wherein the forming the overcoat further includes forming the lower surface of the overcoat in the display area to flat.

11. The method of claim 7, wherein the forming the color filter and the dummy color filter includes:
coating a pigment layer on the second substrate and the light blocking members,
exposing the pigment layer by using a mask, and
developing the exposed pigment layer.

12. The method of claim 11, wherein the mask includes a light blocking part, a transmitting part, and a slit part.

13. The method of claim 12, wherein the pigment layer includes one of red, green, and blue colors.

14. The method of claim 7, wherein the dummy color filter includes a plurality of discrete patterns of a quadrangle shape.

15. A liquid crystal display comprising:
a first substrate including a display area and a peripheral area;
a thin film transistor on the first substrate;
light blocking members in the display area on the first substrate and the thin film transistor, and the peripheral area;
a color filter between light blocking members in the display area, on the first substrate;
a dummy color filter on a light blocking member in the peripheral area;
a passivation layer on the color filter in the display area and the dummy color filter in the peripheral area; and
a pixel electrode on the passivation layer and connected to the thin film transistor, wherein an upper surface of the passivation layer in the peripheral area includes protrusions and depressions.

16. The liquid crystal display of claim 15, wherein a surface roughness (Ra) of the passivation layer in the peripheral area is about 30 nanometers to about 100 nanometers.

17. The liquid crystal display of claim 16, wherein the upper surface of the passivation layer in the display area is flat.

18. The liquid crystal display of claim 15, wherein the dummy color filter includes a plurality of discrete patterns of a quadrangle shape.

19. The liquid crystal display of claim 18, wherein the color filter includes red, green, and blue colors, and the dummy color filter includes at least one of red, green, and blue colors.
